(19) United States
(12) Patent Application Publication
(10) Pub. No.: US 2026/0082903 A1
(43) Pub. Date: Mar. 19, 2026

(54) SEMICONDUCTOR DEVICE

(71) Applicant: Mitsubishi Electric Corporation, Tokyo (JP)

(72) Inventors: Reona FURUKAWA, Tokyo (JP); Koji TANAKA, Tokyo (JP); Takashi FUJIMOTO, Tokyo (JP); Kazuya KONISHI, Tokyo (JP)

(73) Assignee: Mitsubishi Electric Corporation, Tokyo (JP)

(21) Appl. No.: 19/208,169

(22) Filed: May 14, 2025

(30) Foreign Application Priority Data
Sep. 13, 2024 (JP) 2024-158803

(51) Int. Cl. H01L 23/482; H10D 12/00; H10D 64/00

(52) U.S. Cl. CPC H10W 20/484; H10D 12/481; H10D 64/112; H10D 64/117

(57) ABSTRACT

A semiconductor device includes a semiconductor substrate in which a first trench is formed, a gate pad on the semiconductor substrate, first gate wiring and second gate wiring electrically connected to the gate pad, finger wiring that is provided between the first gate wiring and the second gate wiring and is electrically connected to the gate pad, a first main electrode between the first gate wiring and the finger wiring, a second main electrode between the second gate wiring and the finger wiring, a first lower-stage electrode in the first trench, and a first upper-stage electrode provided on the first lower-stage electrode in the first trench, wherein the first lower-stage electrode contacts with the first gate wiring or the second gate wiring and the finger wiring, and the first upper-stage electrode contacts with the first gate wiring or the second gate wiring and the finger wiring.

### BACKGROUND

### Field

The present disclosure relates to a semiconductor device.

### BACKGROUND

JP 2024-45595 A discloses a semiconductor device including an active trench having a gate insulation film that is provided along a trench of a semiconductor substrate and an active portion which is provided in contact with the gate insulation film and is connected to a gate electrode. The active portion is divided into two portions as an upper portion and a lower portion via an intermediate insulation film.

In a semiconductor device as disclosed in JP 2024-45595 A, an electrode in a trench is divided into an upper portion and a lower portion. Thus, an area of the electrode in the trench becomes small, wiring resistance thereby becomes large, and this might cause a delay of a gate signal.

### SUMMARY

The present disclosure has been made to solve the above-described problems, and an object thereof is to provide a semiconductor device that can suppress a delay of a gate signal.

The features and advantages of the present disclosure may be summarized as follows.

According to an aspect of the present disclosure, a semiconductor device includes a semiconductor substrate in which a first trench is formed; a gate pad that is provided on the semiconductor substrate; first gate wiring that is provided on the semiconductor substrate and is electrically connected to the gate pad; second gate wiring that is provided on the semiconductor substrate and is electrically connected to the gate pad; finger wiring that is provided between the first gate wiring and the second gate wiring on the semiconductor substrate and is electrically connected to the gate pad; a first main electrode that is provided between the first gate wiring and the finger wiring on the semiconductor substrate; a second main electrode that is provided between the second gate wiring and the finger wiring on the semiconductor substrate; a first lower-stage electrode that is provided in an internal portion of the first trench; and a first upper-stage electrode that is provided on the first lower-stage electrode via an insulation film in the internal portion of the first trench, wherein the first lower-stage electrode contacts with the first gate wiring or the second gate wiring and the finger wiring, and the first upper-stage electrode contacts with the first gate wiring or the second gate wiring and the finger wiring.

According to an aspect of the present disclosure, a semiconductor device includes a semiconductor substrate in which a first trench is formed; an upper-stage gate pad that is provided on the semiconductor substrate; a lower-stage gate pad that is provided on the semiconductor substrate; first lower-stage gate wiring that is provided on the semiconductor substrate and is electrically connected to the lower-stage gate pad; second lower-stage gate wiring that is provided on the semiconductor substrate and is electrically connected to the lower-stage gate pad; finger wiring that is provided between the first lower-stage gate wiring and the second lower-stage gate wiring on the semiconductor substrate and is electrically connected to the lower-stage gate pad; a first main electrode that is provided between the first lower-stage gate wiring and the finger wiring on the semiconductor substrate; a second main electrode that is provided between the second lower-stage gate wiring and the finger wiring on the semiconductor substrate; upper-stage gate wiring that is provided between the first lower-stage gate wiring or the second lower-stage gate wiring and the finger wiring on the semiconductor substrate and is electrically connected to the upper-stage gate pad; a first lower-stage electrode that is provided in an internal portion of the first trench; and a first upper-stage electrode that is provided on the first lower-stage electrode via an insulation film in the internal portion of the first trench, wherein the first lower-stage electrode contacts with the first lower-stage gate wiring or the second lower-stage gate wiring and the finger wiring, and the first upper-stage electrode contacts with the upper-stage gate wiring.

Other and further objects, features and advantages of the disclosure will appear more fully from the following description.

### BRIEF DESCRIPTION OF DRAWINGS

FIG. 1 is a plan view of a semiconductor device according to a first embodiment.

FIG. 2 is a cross-sectional view of the semiconductor device according to the first embodiment in a perpendicular direction to a direction in which a trench extends.

FIG. 3 is a cross-sectional view of the semiconductor device according to the first embodiment in a direction along the trench.

FIG. 4 is a cross-sectional view of a semiconductor device according to a second embodiment in a direction along the trench.

FIG. 5 is a plan view of a semiconductor device according to a third embodiment.

FIG. 6 is a cross-sectional view of a semiconductor device according to a fourth embodiment in a perpendicular direction to a direction in which the trench extends.

FIG. 7 is a cross-sectional view of the semiconductor device according to the fourth embodiment in a direction along the trench.

FIG. 8 is a plan view of a semiconductor device according to a fifth embodiment.

FIG. 9 is a cross-sectional view of the semiconductor device according to the fifth embodiment in a perpendicular direction to a direction in which the trench extends.

FIG. 10 is a cross-sectional view of the semiconductor device according to the fifth embodiment in a direction along the trench.

FIG. 11 is a plan view of a semiconductor device according to a sixth embodiment.

FIG. 12 is a plan view of a semiconductor device according to a seventh embodiment.

FIG. 13 is a plan view of a semiconductor device according to an eighth embodiment.

FIG. 14 is a cross-sectional view of a semiconductor device according to a ninth embodiment in a perpendicular direction to a direction in which the trench extends.

FIG. 15 is a cross-sectional view of the semiconductor device according to the ninth embodiment in a direction along the trench.

FIG. 16 is a cross-sectional view of a semiconductor device according to a tenth embodiment in a perpendicular direction to a direction in which the trench extends.

FIG. 17 is a plan view of the semiconductor device according to the tenth embodiment.

### DESCRIPTION OF EMBODIMENTS

A semiconductor device according to each embodiment will be described with reference to the accompanying drawings. Components identical or corresponding to each other are indicated by the same reference characters, and repeated description of them is avoided in some cases.

### First Embodiment

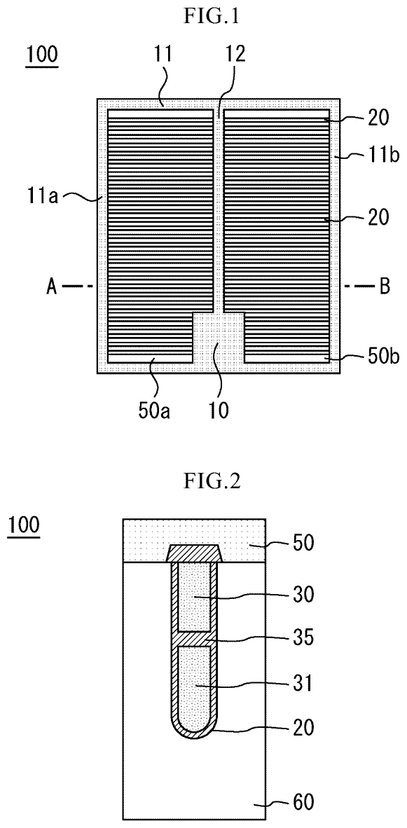

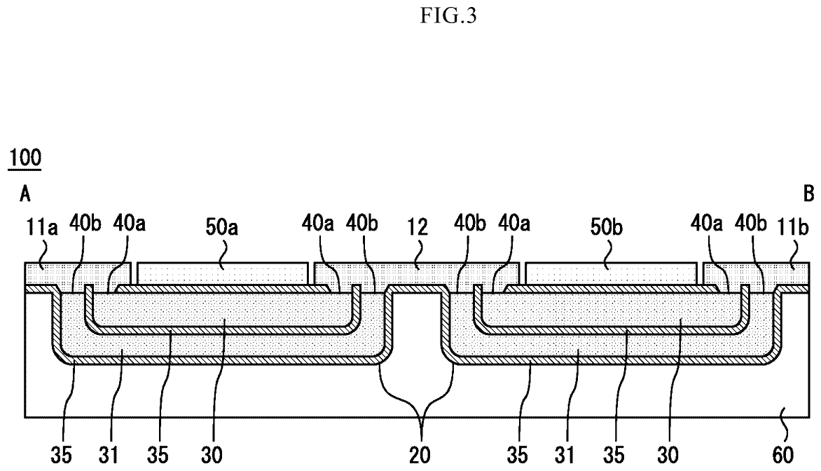

FIG. 1 is a plan view of a semiconductor device 100 according to a first embodiment. FIG. 2 is a cross-sectional view of the semiconductor device 100 according to the first embodiment in a perpendicular direction to a direction in which a trench 20 extends. FIG. 3 is a cross-sectional view of the semiconductor device 100 according to the first embodiment in a direction along the trench 20. In other words, FIG. 3 is a cross-sectional view taken along A-B in FIG. 1. The semiconductor device 100 is an insulated gate bipolar transistor (IGBT), for example. The semiconductor device 100 includes a semiconductor substrate 60. Note that in the cross-sectional views, semiconductor layers formed in the semiconductor substrate 60, collector electrodes provided on a back surface of the semiconductor substrate 60, and so forth are not illustrated.

The semiconductor substrate 60 is a silicon substrate, for example. A plurality of trenches 20 are formed in the semiconductor substrate 60. The plurality of trenches 20 extend along an A-B straight line in FIG. 1. A gate pad 10 is provided on the semiconductor substrate 60. A gate signal is input from an outside to the gate pad 10. On the semiconductor substrate 60, gate wiring 11a and 11b and finger wiring 12 are provided which are electrically connected to the gate pad 10. The finger wiring 12 is provided between the gate wiring 11a and 11b. The gate wiring 11a and 11b and the finger wiring 12 constitute gate wiring 11. The gate wiring 11 may be metal wiring and may be formed of aluminum, for example.

On the semiconductor substrate 60, a main electrode 50a is provided between the gate wiring 11a and the finger wiring 12. On the semiconductor substrate 60, a main electrode 50b is provided between the gate wiring 11b and the finger wiring 12. In FIG. 2, the main electrode 50a or the main electrode 50b is illustrated as a main electrode 50. Each of the main electrodes 50a and 50b is an emitter electrode and is electrically connected to an emitter pad, which is not illustrated. In plan view, the main electrodes 50a and 50b are surrounded by the gate wiring 11 including the gate wiring 11a and 11b and the finger wiring 12. The finger wiring 12 is arranged to divide the main electrode 50.

In an internal portion of the trench 20, an upper-stage electrode 30 and a lower-stage electrode 31 as gate electrodes are provided. The upper-stage electrode 30 and the lower-stage electrode 31 are formed of polysilicon, for example. The upper-stage electrode 30 is provided on the lower-stage electrode 31 via an insulation film 35. In other words, the insulation film 35 divides the upper-stage electrode 30 from the lower-stage electrode 31. As illustrated in FIG. 2, the insulation film 35 is provided to surround both sides and upper and lower sides of each of the lower-stage electrode 31 and the upper-stage electrode 30. The insulation film 35 is formed of SiO2, for example.

As illustrated in FIG. 3, the upper-stage electrode 30 contacts with the gate wiring 11a, the gate wiring 11b and the finger wiring 12. Specifically, an opening is formed in the insulation film 35, and an upper-stage contact 40a is thereby formed. In the upper-stage contact 40a, the upper-stage electrode 30 contacts with the gate wiring 11. The lower-stage electrode 31 contacts with the gate wiring 11a, the gate wiring 11b and the finger wiring 12. Specifically, an opening is formed in the insulation film 35, and a lower-stage contact 40b is thereby formed. In the lower-stage contact 40b, the lower-stage electrode 31 contacts with the gate wiring 11.

Note that the trench 20 extending in an A-B direction is divided directly below the finger wiring 12. In the present embodiment and the following embodiments, a plurality of portions resulting from division in the A-B direction may collectively be considered to be one trench 20.

Next, effects of the present embodiment will be described. In the present embodiment, the main electrode 50 is divided by the finger wiring 12. Each of the upper-stage electrode 30 and the lower-stage electrode 31 contacts with the gate wiring 11a or 11b and the finger wiring 12 and is thereby electrically connected to the gate wiring 11. In this case, compared to a case where no finger wiring 12 is provided, a length of the trench 20 in the A-B direction becomes short in a case where the finger wiring 12 is provided. In general, wiring resistance of the gate wiring 11 is smaller than those of electrodes in the trench 20. Consequently, in the present embodiment, the wiring resistance can be suppressed, and a delay of the gate signal can be suppressed. In particular, even in a case where the gate electrode is divided into the upper-stage electrode 30 and the lower-stage electrode 31 and an area of the gate electrode thereby becomes small, the delay of the gate signal can be suppressed. Because the delay of the gate signal can be suppressed, a chip size can be made large, for example.

The trench 20 of the present embodiment is divided directly below the finger wiring 12 in a direction from the gate wiring 11a toward the gate wiring 11b. Thus, the trench 20 becomes further shorter, and the delay of the gate signal can thereby be suppressed.

The upper-stage electrode 30 may contact with only one of the gate wiring 11a and the gate wiring 11b. Similarly, the lower-stage electrode 31 may contact with only one of the gate wiring 11a and the gate wiring 11b. In an example in FIG. 3, the gate electrode in a left-side portion of the trench 20 divided into left and right portions contacts with the gate wiring 11a and the finger wiring 12, and the gate electrode in a right-side portion contacts with the gate wiring 11b and the finger wiring 12. In this case, an effect of suppressing the delay of the gate signal can also be obtained.

A shape of the gate wiring 11 is not limited to a shape illustrated in FIG. 1. The semiconductor substrate 60 may be made with a wide-bandgap semiconductor. The wide-bandgap semiconductor may be formed of silicon carbide, a gallium-nitride-based material, or a diamond, for example.

These modifications can be appropriately applied to semiconductor devices according to embodiments below. Meanwhile, for the semiconductor devices according to the embodiments below, dissimilarities with the first embodiment will mainly be explained as they have many similarities with the first embodiment.

### Second Embodiment

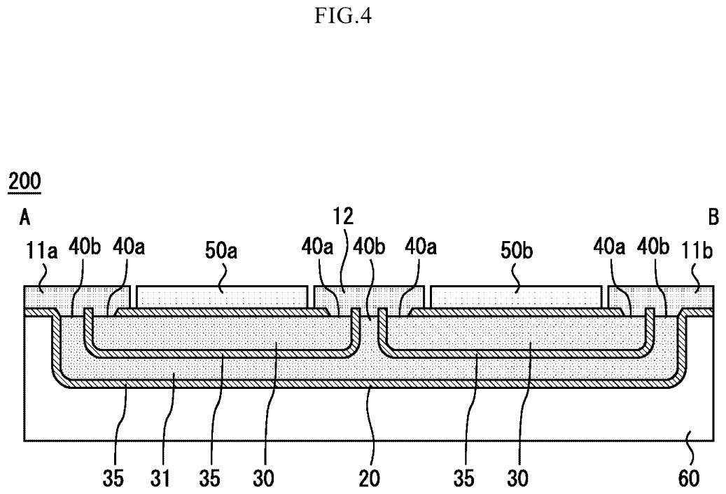

FIG. 4 is a cross-sectional view of a semiconductor device 200 according to a second embodiment in a direction along the trench 20. In the semiconductor device 200, the trench 20 is not divided directly below the finger wiring 12. Also in such a structure, as in the first embodiment, the wiring resistance can be suppressed, and the delay of the gate signal can be suppressed.

### Third Embodiment

FIG. 5 is a plan view of a semiconductor device 300 according to a third embodiment.

The semiconductor device 300 is different from the semiconductor device 100 of the first embodiment in the point that the semiconductor device 300 includes a plurality of pieces of finger wiring 12a and 12b. Other configurations are similar to configurations of the semiconductor device 100. In an example in FIG. 5, the main electrode 50 is divided into three main electrodes 50a, 50b, and 50c by the finger wiring 12a and 12b. The number of pieces of finger wiring 12 is not limited.

As in the first embodiment, the trench 20 may be divided directly below the finger wiring 12a and 12b. In a case where two pieces of finger wiring 12 are provided, the trench 20 is divided into three portions in the A-B direction. In the present embodiment, the trench 20 can be made further shorter, and the delay of the gate signal can further be suppressed than the first embodiment. Note that as in the second embodiment, the trench 20 does not have to be divided directly below the finger wiring 12a or 12b.

### Fourth Embodiment

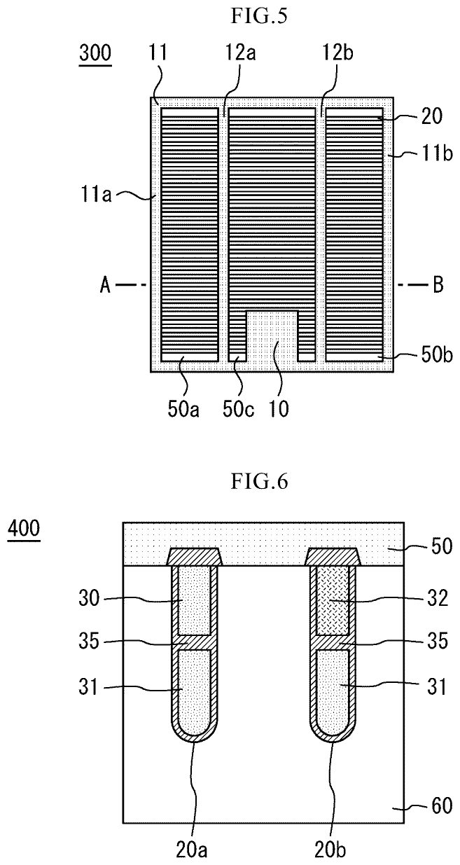

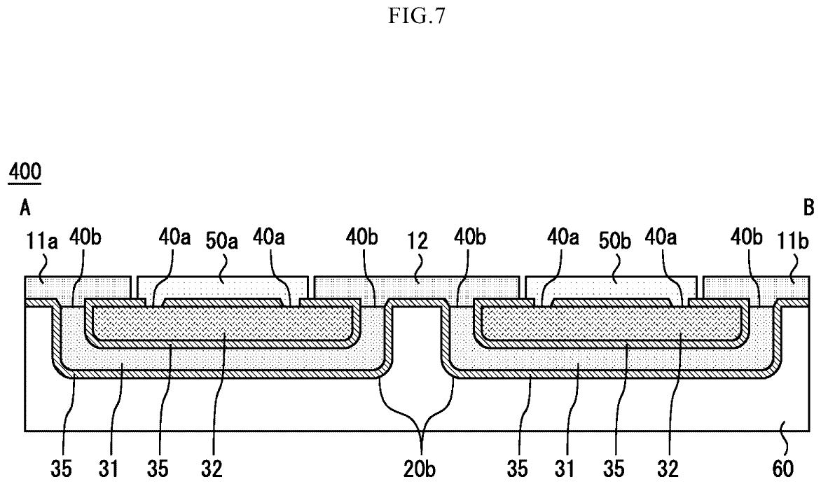

FIG. 6 is a cross-sectional view of a semiconductor device 400 according to a fourth embodiment in a perpendicular direction to a direction in which the trench 20 extends. FIG. 7 is a cross-sectional view of the semiconductor device 400 according to the fourth embodiment in a direction along the trench 20. In the present embodiment, two kinds of trenches 20a and 20b are formed in the semiconductor substrate 60. A structure of the trench 20a is similar to that of the trench 20 of the first embodiment. In an internal portion of the trench 20b, the lower-stage electrode 31 and an upper-stage electrode 32 are provided, the upper-stage electrode 32 being provided on the lower-stage electrode 31 via the insulation film 35. Other structures are similar to structures of the first embodiment.

As illustrated in FIG. 7, the lower-stage electrode 31 of the trench 20b contacts with the gate wiring 11a, the gate wiring 11b and the finger wiring 12. The upper-stage electrode 32 of the trench 20b contacts with the main electrode 50a and the main electrode 50b. In other words, the upper-stage electrode 30 and the lower-stage electrode 31 of the trench 20a and the lower-stage electrode 31 of the trench 20b are active electrodes which are electrically connected to the gate pad 10. The upper-stage electrode 32 of the trench 20b is a dummy electrode.

In the present embodiment, by the upper-stage electrode 32 to be connected to the main electrode 50, it becomes possible to adjust input capacitance.

The lower-stage electrode 31 of the trench 20b may contact with only one of the gate wiring 11a and the gate wiring 11b. The upper-stage electrode 32 of the trench 20b may contact with only one of the main electrode 50a and the main electrode 50b. In an example in FIG. 7, the lower-stage electrode 31 in a left-side portion of the trench 20b divided into left and right portions contacts with the gate wiring 11a and the finger wiring 12, and the lower-stage electrode 31 in a right-side portion contacts with the gate wiring 11b and the finger wiring 12. The upper-stage electrode 32 in the left-side portion of the trench 20b divided into the left and right portions contacts with the main electrode 50a, and the upper-stage electrode 32 in the right-side portion contacts with the main electrode 50b.

Arrangement of the trench 20b is not limited. For example, the trenches 20a and 20b may alternately be provided. It is sufficient that a part of the plurality of trenches 20 illustrated in FIG. 1 is substituted by the trenches 20b.

### Fifth Embodiment

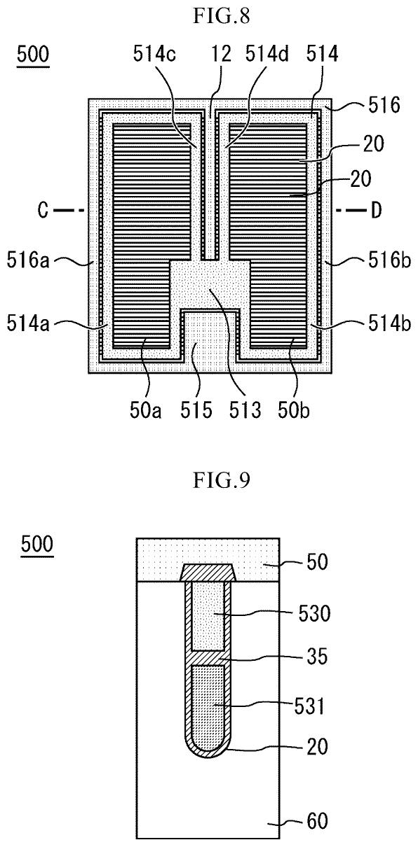

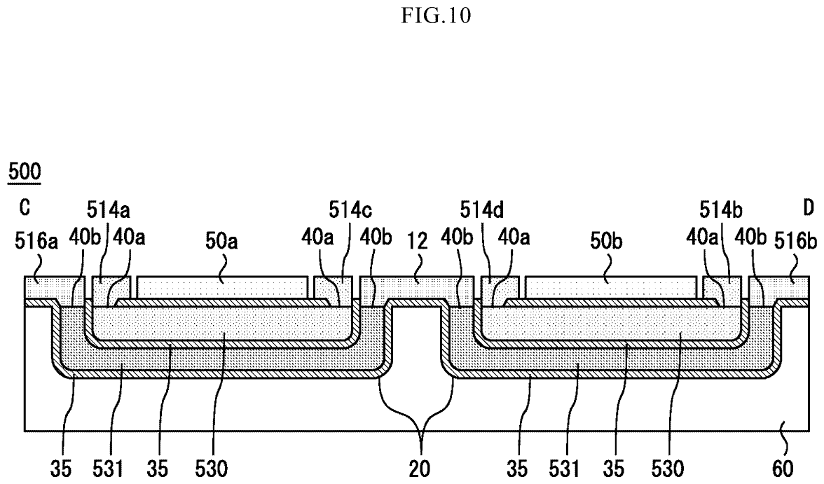

FIG. 8 is a plan view of a semiconductor device 500 according to a fifth embodiment. FIG. 9 is a cross-sectional view of the semiconductor device 500 according to the fifth embodiment in a perpendicular direction to a direction in which the trench 20 extends. FIG. 10 is a cross-sectional view of the semiconductor device 500 according to the fifth embodiment in a direction along the trench 20. In other words, FIG. 10 is a cross-sectional view taken along C-D in FIG. 8. The semiconductor device 500 is an IGBT, for example. The semiconductor device 500 includes the semiconductor substrate 60. Note that in the cross-sectional views, semiconductor layers formed in the semiconductor substrate 60, collector electrodes provided on the back surface of the semiconductor substrate 60, and so forth are not illustrated.

On the semiconductor substrate 60, an upper-stage gate pad 513, a lower-stage gate pad 515, upper-stage gate wiring 514 electrically connected to the upper-stage gate pad 513, and lower-stage gate wiring 516 electrically connected to the lower-stage gate pad 515 are provided. The gate signal is input from the outside to the upper-stage gate pad 513 and the lower-stage gate pad 515. The upper-stage gate pad 513 and the lower-stage gate pad 515 are adjacent to each other, for example.

The lower-stage gate wiring 516 includes lower-stage gate wiring 516a and 516b which are electrically connected to the lower-stage gate pad 515. On the semiconductor substrate 60, the finger wiring 12 electrically connected to the lower-stage gate pad 515 is provided between the lower-stage gate wiring 516a and 516b.

On the semiconductor substrate 60, the main electrode 50a is provided between the lower-stage gate wiring 516a and the finger wiring 12. On the semiconductor substrate 60, the main electrode 50b is provided between the lower-stage gate wiring 516b and the finger wiring 12. In FIG. 9, the main electrode 50a or the main electrode 50b is illustrated as the main electrode 50. Each of the main electrodes 50a and 50b is an emitter electrode and is electrically connected to an emitter pad, which is not illustrated.

The upper-stage gate wiring 514 includes upper-stage gate wiring 514a to 514d which are electrically connected to the upper-stage gate pad 513. The upper-stage gate wiring 514a is provided between the lower-stage gate wiring 516a and the main electrode 50a. The upper-stage gate wiring 514b is provided between the lower-stage gate wiring 516b and the main electrode 50b. The upper-stage gate wiring 514c is provided between the finger wiring 12 and the main electrode 50a. The upper-stage gate wiring 514d is provided between the finger wiring 12 and the main electrode 50b. In plan view, the main electrode 50a and the main electrode 50b are surrounded by the upper-stage gate wiring 514.

The semiconductor device 500 includes a lower-stage electrode 531, which is provided in an internal portion of the trench 20, and an upper-stage electrode 530, which is provided on the lower-stage electrode 531 via the insulation film 35 in the internal portion of the trench 20. The upper-stage electrode 530 contacts with the upper-stage gate wiring 514a, the upper-stage gate wiring 514b, the upper-stage gate wiring 514c, and the upper-stage gate wiring 514d. Specifically, an opening is formed in the insulation film 35, and the upper-stage contact 40a is thereby formed. In the upper-stage contact 40a, the upper-stage electrode 530 contacts with the upper-stage gate wiring 514. The lower-stage electrode 531 contacts with the lower-stage gate wiring 516a, the lower-stage gate wiring 516b and the finger wiring 12. Specifically, an opening is formed in the insulation film 35, and the lower-stage contact 40b is thereby formed. In the lower-stage contact 40b, the lower-stage electrode 531 contacts with the lower-stage gate wiring 516.

In an example in FIG. 10, the upper-stage electrode 530 in a left-side portion of the trench 20 divided into left and right portions contacts with the upper-stage gate wiring 514a and 514c, and the upper-stage electrode 530 in a right-side portion contacts with the upper-stage gate wiring 514b and 514d. The lower-stage electrode 531 in the left-side portion of the trench 20 divided into the left and right portions contacts with the lower-stage gate wiring 516a and the finger wiring 12, and the lower-stage electrode 531 in the right-side portion contacts with the lower-stage gate wiring 516b and the finger wiring 12.

Also in the present embodiment, the wiring resistance is suppressed, and the delay of the gate signal can thereby be suppressed. For example, the lower-stage gate pad 515 is connected to the upper-stage gate pad 513, and the upper-stage electrode 530 and the lower-stage electrode 531 can thereby be caused to have the same potential. For connection, for example, a wire can be used. In addition, the lower-stage gate pad 515 is connected to the main electrode 50, and the lower-stage electrode 531 can thereby be caused to have an emitter potential. In such a manner, as for the electrodes in the trench 20, a plurality of states can be realized. A potential of the lower-stage electrode 531 can be changed in accordance with connection, and capacitance adjustment can easily be carried out.

Different gate signals can respectively be input to the upper-stage electrode 530 and the lower-stage electrode 531. For example, timings of the gate signals can be changed for the upper-stage electrode 530 and the lower-stage electrode 531. Accordingly, adjustment of carriers around the trench 20 becomes easy, and loss in a switching action can thereby be reduced.

Shapes of the upper-stage gate wiring 514 and the lower-stage gate wiring 516 are not limited to shapes illustrated in FIG. 8. It is sufficient that on the semiconductor substrate 60, the upper-stage gate wiring 514 is provided between the lower-stage gate wiring 516a or the lower-stage gate wiring 516b and the finger wiring 12. It is sufficient that the upper-stage electrode 530 contacts any portion of the upper-stage gate wiring 514. For example, the upper-stage electrode 530 may contact with one or more of the upper-stage gate wiring 514a, 514b, 514c, and 514d. The lower-stage electrode 531 may contact with only one of the lower-stage gate wiring 516a and the lower-stage gate wiring 516b.

Also in the present embodiment, the trench 20 is divided directly below the finger wiring 12 in a direction from the lower-stage gate wiring 516a toward the lower-stage gate wiring 516b. As in the second embodiment, the trench 20 does not have to be divided.

### Sixth Embodiment

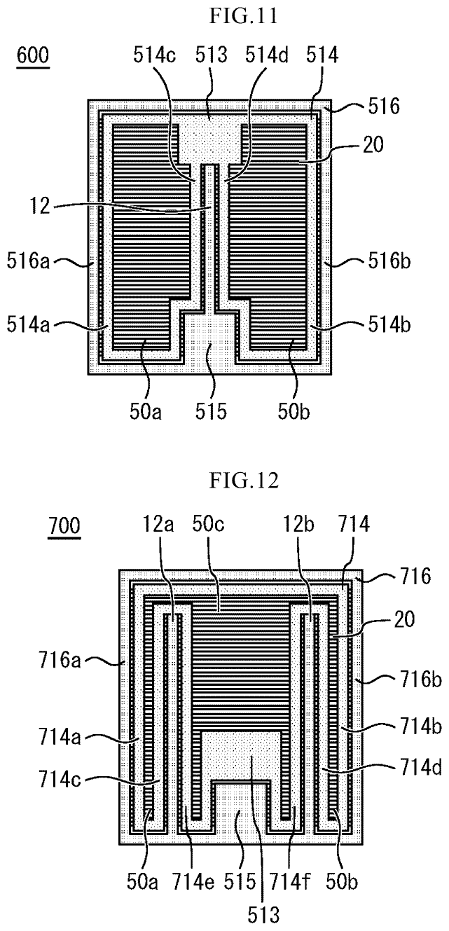

FIG. 11 is a plan view of a semiconductor device 600 according to a sixth embodiment. In the present embodiment, the upper-stage gate pad 513 and the lower-stage gate pad 515 are respectively provided on one side and the other side of the semiconductor substrate 60. The finger wiring 12 is provided between the upper-stage gate pad 513 and the lower-stage gate pad 515. Other configurations are similar to configurations of the fifth embodiment.

### Seventh Embodiment

FIG. 12 is a plan view of a semiconductor device 700 according to a seventh embodiment. The semiconductor device 700 includes the plurality of pieces of finger wiring 12a and 12b. Other configurations are similar to the configurations of the fifth embodiment.

A lower-stage gate wiring 716 includes lower-stage gate wiring 716a and 716b which are electrically connected to the lower-stage gate pad 515. On the semiconductor substrate 60, the finger wiring 12a and 12b, which are electrically connected to the lower-stage gate pad 515, are provided between the lower-stage gate wiring 716a and 716b.

On the semiconductor substrate 60, the main electrode 50a is provided between the lower-stage gate wiring 716a and the finger wiring 12a. On the semiconductor substrate 60, the main electrode 50b is provided between the lower-stage gate wiring 716b and the finger wiring 12b. On the semiconductor substrate 60, the main electrode 50c is provided between the finger wiring 12a and 12b.

An upper-stage gate wiring 714 includes upper-stage gate wiring 714a to 714f which are electrically connected to the upper-stage gate pad 513. The upper-stage gate wiring 714a is provided between the lower-stage gate wiring 716a and the main electrode 50a. The upper-stage gate wiring 714b is provided between the lower-stage gate wiring 716b and the main electrode 50b. The upper-stage gate wiring 714c is provided between the finger wiring 12a and the main electrode 50a. The upper-stage gate wiring 714d is provided between the finger wiring 12b and the main electrode 50b. The upper-stage gate wiring 714e is provided between the finger wiring 12a and the main electrode 50c. The upper-stage gate wiring 714f is provided between the finger wiring 12b and the main electrode 50c.

In an example in FIG. 12, the main electrode 50 is divided into three main electrodes 50a, 50b, and 50c by the finger wiring 12a and 12b. The number of pieces of finger wiring 12 is not limited. As in the first embodiment, the trench 20 may be divided directly below the finger wiring 12a and 12b. As in the second embodiment, the trench 20 does not have to be divided directly below the finger wiring 12a or 12b.

### Eighth Embodiment

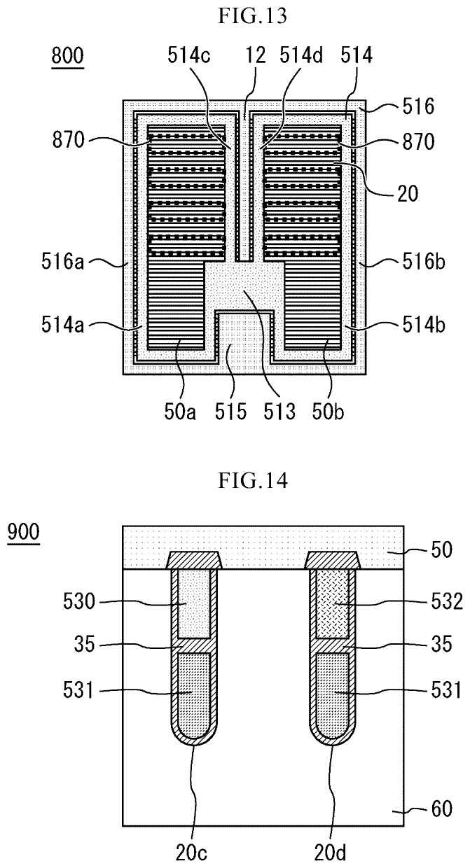

FIG. 13 is a plan view of a semiconductor device 800 according to an eighth embodiment. The semiconductor device 800 is different from the fifth embodiment in the point that a diode region 870 is formed in the semiconductor substrate 60 in addition to an IGBT region. Other configurations are similar to the configurations of the fifth embodiment. In other words, the semiconductor device 800 may be a reverse-conducting (RC)-IGBT. Note that the semiconductor device 100 of the first embodiment may be formed as an RC-IGBT.

### Ninth Embodiment

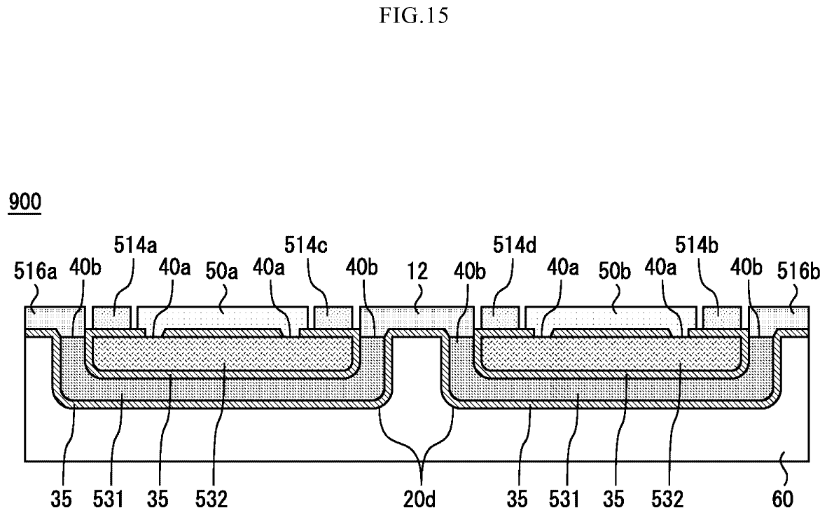

FIG. 14 is a cross-sectional view of a semiconductor device 900 according to a ninth embodiment in a perpendicular direction to a direction in which the trench 20 extends. FIG. 15 is a cross-sectional view of the semiconductor device 900 according to the ninth embodiment in a direction along the trench 20. In the present embodiment, two kinds of trenches 20c and 20d are formed in the semiconductor substrate 60. A structure of the trench 20c is similar to that of the trench 20 of the fifth embodiment. In an internal portion of the trench 20d, the lower-stage electrode 531 and an upper-stage electrode 532 are provided, the upper-stage electrode 532 being provided on the lower-stage electrode 531 via the insulation film 35. Other structures are similar to structures of the fifth embodiment.

As illustrated in FIG. 15, the lower-stage electrode 531 of the trench 20d contacts with the lower-stage gate wiring 516a, the lower-stage gate wiring 516b and the finger wiring 12. The upper-stage electrodes 532 of the trench 20d contact with the main electrode 50a and the main electrode 50b. The upper-stage electrode 530 of the trench 20c is an active electrode which is electrically connected to the upper-stage gate pad 513. The upper-stage electrode 532 of the trench 20d is a dummy electrode.

In an example in FIG. 15, the lower-stage electrode 531 in a left-side portion of the trench 20d divided into left and right portions contacts with the lower-stage gate wiring 516a and the finger wiring 12, and the lower-stage electrode 531 in a right-side portion contacts with the lower-stage gate wiring 516b and the finger wiring 12. The upper-stage electrode 532 in the left-side portion of the trench 20d divided into the left and right portions contacts with the main electrode 50a, and the upper-stage electrode 532 in the right-side portion contacts with the main electrode 50b.

In the present embodiment, by the upper-stage electrode 532 to be connected to the main electrode 50, it becomes possible to adjust capacitance. The potential of the lower-stage electrode 531 can be changed by changing connection of the lower-stage gate pad 515, and capacitance adjustment can more easily be carried out.

Also in the present embodiment, the lower-stage electrode 531 of the trench 20d may contact with only one of the lower-stage gate wiring 516a and the lower-stage gate wiring 516b. The upper-stage electrode 532 of the trench 20d may contact with only one of the main electrode 50a and the main electrode 50b.

### Tenth Embodiment

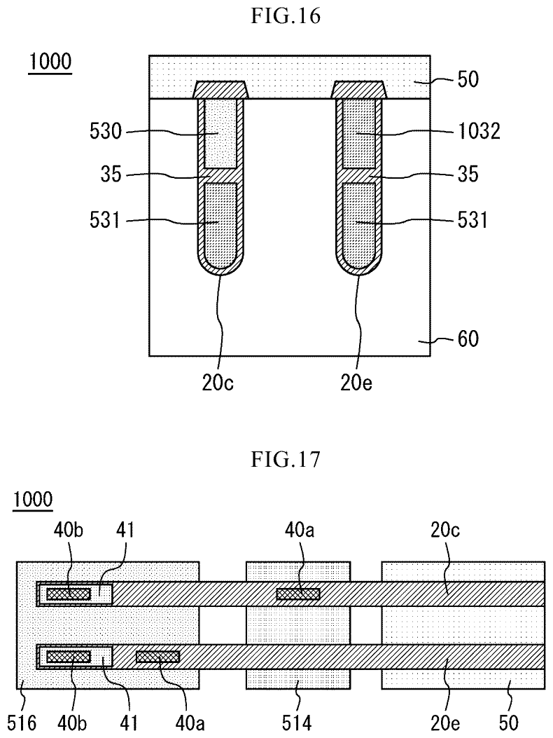

FIG. 16 is a cross-sectional view of a semiconductor device 1000 according to a tenth embodiment in a perpendicular direction to a direction in which the trench 20 extends. FIG. 17 is a plan view of the semiconductor device 1000 according to the tenth embodiment. The present embodiment is different from the ninth embodiment in the point that a trench 20e is provided instead of the trench 20d. Other configurations are similar to configurations of the ninth embodiment.

In an internal portion of the trench 20e, the lower-stage electrode 531 and an upper-stage electrode 1032 are provided, the upper-stage electrode 1032 being provided on the lower-stage electrode 531 via the insulation film 35. The lower-stage electrode 531 of the trench 20e contacts with the lower-stage gate wiring 516a, the lower-stage gate wiring 516b and the finger wiring 12. The upper-stage electrode 1032 of the trench 20e contacts with the lower-stage gate wiring 516a, the lower-stage gate wiring 516b and the finger wiring 12.

As illustrated in FIG. 17, in a lower-stage pulling region 41, the lower-stage electrode 531 of the trench 20c is electrically connected to the lower-stage gate wiring 516 via the lower-stage contact 40b. The upper-stage electrode 530 of the trench 20c is electrically connected to the upper-stage gate wiring 514 via the upper-stage contact 40a. The upper-stage electrode 1032 of the trench 20e is electrically connected to the lower-stage gate wiring 516 via the upper-stage contact 40a. In the lower-stage pulling region 41, the lower-stage electrode 531 of the trench 20e is electrically connected to the lower-stage gate wiring 516 via the lower-stage contact 40b.

Also in the present embodiment, potentials of the lower-stage electrode 531 and the upper-stage electrode 1032 can be changed by changing connection of the gate pad, and capacitance adjustment can easily be carried out.

Note that it is sufficient that each of the lower-stage electrode 531 and the upper-stage electrode 1032 contacts with one of the lower-stage gate wiring 516a and the lower-stage gate wiring 516b.

Hereinafter, various aspects of the present disclosure will be collectively described as appendixes.

### (Appendix 1)

A semiconductor device comprising:
a semiconductor substrate in which a first trench is formed;
a gate pad that is provided on the semiconductor substrate;
first gate wiring that is provided on the semiconductor substrate and is electrically connected to the gate pad;
second gate wiring that is provided on the semiconductor substrate and is electrically connected to the gate pad;
finger wiring that is provided between the first gate wiring and the second gate wiring on the semiconductor substrate and is electrically connected to the gate pad;
a first main electrode that is provided between the first gate wiring and the finger wiring on the semiconductor substrate;
a second main electrode that is provided between the second gate wiring and the finger wiring on the semiconductor substrate;
a first lower-stage electrode that is provided in an internal portion of the first trench; and
a first upper-stage electrode that is provided on the first lower-stage electrode via an insulation film in the internal portion of the first trench, wherein
the first lower-stage electrode contacts with the first gate wiring or the second gate wiring and the finger wiring, and
the first upper-stage electrode contacts with the first gate wiring or the second gate wiring and the finger wiring.

### (Appendix 2)

The semiconductor device according to appendix 1, wherein
in plan view, the first main electrode and the second main electrode are surrounded by gate wiring which includes the first gate wiring, the second gate wiring, and the finger wiring.

### (Appendix 3)

The semiconductor device according to appendix 1 or 2, wherein
the first trench is divided directly below the finger wiring in a direction from the first gate wiring toward the second gate wiring.

### (Appendix 4)

The semiconductor device according to any one of appendixes 1 to 3, comprising
a plurality of pieces of the finger wiring.

### (Appendix 5)

The semiconductor device according to any one of appendixes 1 to 4, comprising:
a second lower-stage electrode that is provided in an internal portion of a second trench which is formed in the semiconductor substrate; and
a second upper-stage electrode that is provided on the second lower-stage electrode via an insulation film in the internal portion of the second trench, wherein
the second lower-stage electrode contacts with the first gate wiring or the second gate wiring and the finger wiring, and
the second upper-stage electrode contacts with the first main electrode or the second main electrode.

### (Appendix 6)

A semiconductor device comprising:
a semiconductor substrate in which a first trench is formed;
an upper-stage gate pad that is provided on the semiconductor substrate;
a lower-stage gate pad that is provided on the semiconductor substrate;
first lower-stage gate wiring that is provided on the semiconductor substrate and is electrically connected to the lower-stage gate pad;
second lower-stage gate wiring that is provided on the semiconductor substrate and is electrically connected to the lower-stage gate pad;
finger wiring that is provided between the first lower-stage gate wiring and the second lower-stage gate wiring on the semiconductor substrate and is electrically connected to the lower-stage gate pad;
a first main electrode that is provided between the first lower-stage gate wiring and the finger wiring on the semiconductor substrate;
a second main electrode that is provided between the second lower-stage gate wiring and the finger wiring on the semiconductor substrate;
upper-stage gate wiring that is provided between the first lower-stage gate wiring or the second lower-stage gate wiring and the finger wiring on the semiconductor substrate and is electrically connected to the upper-stage gate pad;
a first lower-stage electrode that is provided in an internal portion of the first trench; and
a first upper-stage electrode that is provided on the first lower-stage electrode via an insulation film in the internal portion of the first trench, wherein
the first lower-stage electrode contacts with the first lower-stage gate wiring or the second lower-stage gate wiring and the finger wiring, and
the first upper-stage electrode contacts with the upper-stage gate wiring.

### (Appendix 7)

The semiconductor device according to appendix 6, wherein
the upper-stage gate wiring includes:
first upper-stage gate wiring that is provided between the first lower-stage gate wiring and the first main electrode and is electrically connected to the upper-stage gate pad;
second upper-stage gate wiring that is provided between the second lower-stage gate wiring and the second main electrode and is electrically connected to the upper-stage gate pad;
third upper-stage gate wiring that is provided between the finger wiring and the first main electrode and is electrically connected to the upper-stage gate pad; and
fourth upper-stage gate wiring that is provided between the finger wiring and the second main electrode and is electrically connected to the upper-stage gate pad, and
the first upper-stage electrode contacts with the first upper-stage gate wiring, the second upper-stage gate wiring, the third upper-stage gate wiring, and the fourth upper-stage gate wiring.

### (Appendix 8)

The semiconductor device according to appendix 6 or 7, wherein
in plan view, the first main electrode and the second main electrode are surrounded by the upper-stage gate wiring.

### (Appendix 9)

The semiconductor device according to any one of appendixes 6 to 8, wherein
the first trench is divided directly below the finger wiring in a direction from the first lower-stage gate wiring toward the second lower-stage gate wiring.

### (Appendix 10)

The semiconductor device according to any one of appendixes 6 to 9, wherein
the upper-stage gate pad and the lower-stage gate pad are adjacent to each other.

### (Appendix 11)

The semiconductor device according to any one of appendixes 6 to 9, wherein
the finger wiring is provided between the upper-stage gate pad and the lower-stage gate pad.

### (Appendix 12)

The semiconductor device according to any one of appendixes 6 to 11, comprising
a plurality of pieces of the finger wiring.

### (Appendix 13)

The semiconductor device according to any one of appendixes 6 to 12, comprising:
a second lower-stage electrode that is provided in an internal portion of a second trench which is formed in the semiconductor substrate; and
a second upper-stage electrode that is provided on the second lower-stage electrode via an insulation film in the internal portion of the second trench, wherein
the second lower-stage electrode contacts with the first lower-stage gate wiring or the second lower-stage gate wiring and the finger wiring, and
the second upper-stage electrode contacts with the first main electrode or the second main electrode.

### (Appendix 14)

The semiconductor device according to any one of appendixes 6 to 12, comprising:
a second lower-stage electrode that is provided in an internal portion of a second trench which is formed in the semiconductor substrate; and
a second upper-stage electrode that is provided on the second lower-stage electrode via an insulation film in the internal portion of the second trench, wherein
the second lower-stage electrode contacts with the first lower-stage gate wiring or the second lower-stage gate wiring and the finger wiring, and
the second upper-stage electrode contacts with the first lower-stage gate wiring or the second lower-stage gate wiring and the finger wiring.

### (Appendix 15)

The semiconductor device according to any one of appendixes 1 to 14, wherein the semiconductor substrate is made with a wide band gap semiconductor.

### (Appendix 16)

The semiconductor device according to appendix 15, wherein the wide band gap semiconductor is silicon carbide, gallium-nitride-based material or diamond.

In the semiconductor device according to the first disclosure, each of the first lower-stage electrode and the first upper-stage electrode contacts with the first gate wiring or the second gate wiring and the finger wiring. Accordingly, the wiring resistance can be suppressed, and the delay of the gate signal can be suppressed.

In the semiconductor device according to the second disclosure, the first lower-stage electrode contacts with the first lower-stage gate wiring or the second lower-stage gate wiring and the finger wiring. Accordingly, the wiring resistance can be suppressed, and the delay of the gate signal can be suppressed.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-158803, filed on Sep. 13, 2024 including specification, claims, drawings and summary, on which the Convention priority of the present application is based, are incorporated herein by reference in its entirety.

1. A semiconductor device comprising:
a semiconductor substrate in which a first trench is formed;
a gate pad that is provided on the semiconductor substrate;
first gate wiring that is provided on the semiconductor substrate and is electrically connected to the gate pad;
second gate wiring that is provided on the semiconductor substrate and is electrically connected to the gate pad;
finger wiring that is provided between the first gate wiring and the second gate wiring on the semiconductor substrate and is electrically connected to the gate pad;
a first main electrode that is provided between the first gate wiring and the finger wiring on the semiconductor substrate;
a second main electrode that is provided between the second gate wiring and the finger wiring on the semiconductor substrate;
a first lower-stage electrode that is provided in an internal portion of the first trench; and
a first upper-stage electrode that is provided on the first lower-stage electrode via an insulation film in the internal portion of the first trench, wherein
the first lower-stage electrode contacts with the first gate wiring or the second gate wiring and the finger wiring, and
the first upper-stage electrode contacts with the first gate wiring or the second gate wiring and the finger wiring.

2. The semiconductor device according to claim 1, wherein
in plan view, the first main electrode and the second main electrode are surrounded by gate wiring which includes the first gate wiring, the second gate wiring, and the finger wiring.

3. The semiconductor device according to claim 1, wherein
the first trench is divided directly below the finger wiring in a direction from the first gate wiring toward the second gate wiring.

4. The semiconductor device according to claim 1, comprising
a plurality of pieces of the finger wiring.

5. The semiconductor device according to claim 1, comprising:
a second lower-stage electrode that is provided in an internal portion of a second trench which is formed in the semiconductor substrate; and
a second upper-stage electrode that is provided on the second lower-stage electrode via an insulation film in the internal portion of the second trench, wherein
the second lower-stage electrode contacts with the first gate wiring or the second gate wiring and the finger wiring, and
the second upper-stage electrode contacts with the first main electrode or the second main electrode.

6. A semiconductor device comprising:
a semiconductor substrate in which a first trench is formed;
an upper-stage gate pad that is provided on the semiconductor substrate;
a lower-stage gate pad that is provided on the semiconductor substrate;
first lower-stage gate wiring that is provided on the semiconductor substrate and is electrically connected to the lower-stage gate pad;
second lower-stage gate wiring that is provided on the semiconductor substrate and is electrically connected to the lower-stage gate pad;
finger wiring that is provided between the first lower-stage gate wiring and the second lower-stage gate wiring on the semiconductor substrate and is electrically connected to the lower-stage gate pad;
a first main electrode that is provided between the first lower-stage gate wiring and the finger wiring on the semiconductor substrate;
a second main electrode that is provided between the second lower-stage gate wiring and the finger wiring on the semiconductor substrate;
upper-stage gate wiring that is provided between the first lower-stage gate wiring or the second lower-stage gate wiring and the finger wiring on the semiconductor substrate and is electrically connected to the upper-stage gate pad;
a first lower-stage electrode that is provided in an internal portion of the first trench; and
a first upper-stage electrode that is provided on the first lower-stage electrode via an insulation film in the internal portion of the first trench, wherein
the first lower-stage electrode contacts with the first lower-stage gate wiring or the second lower-stage gate wiring and the finger wiring, and
the first upper-stage electrode contacts with the upper-stage gate wiring.

7. The semiconductor device according to claim 6, wherein
the upper-stage gate wiring includes:
first upper-stage gate wiring that is provided between the first lower-stage gate wiring and the first main electrode and is electrically connected to the upper-stage gate pad;
second upper-stage gate wiring that is provided between the second lower-stage gate wiring and the second main electrode and is electrically connected to the upper-stage gate pad;
third upper-stage gate wiring that is provided between the finger wiring and the first main electrode and is electrically connected to the upper-stage gate pad; and
fourth upper-stage gate wiring that is provided between the finger wiring and the second main electrode and is electrically connected to the upper-stage gate pad, and
the first upper-stage electrode contacts with the first upper-stage gate wiring, the second upper-stage gate wiring, the third upper-stage gate wiring, and the fourth upper-stage gate wiring.

8. The semiconductor device according to claim 6, wherein
in plan view, the first main electrode and the second main electrode are surrounded by the upper-stage gate wiring.

9. The semiconductor device according to claim 6, wherein
the first trench is divided directly below the finger wiring in a direction from the first lower-stage gate wiring toward the second lower-stage gate wiring.

10. The semiconductor device according to claim 6, wherein
the upper-stage gate pad and the lower-stage gate pad are adjacent to each other.

11. The semiconductor device according to claim 6, wherein
the finger wiring is provided between the upper-stage gate pad and the lower-stage gate pad.

12. The semiconductor device according to claim 6, comprising
a plurality of pieces of the finger wiring.

13. The semiconductor device according to claim 6, comprising:
a second lower-stage electrode that is provided in an internal portion of a second trench which is formed in the semiconductor substrate; and
a second upper-stage electrode that is provided on the second lower-stage electrode via an insulation film in the internal portion of the second trench, wherein
the second lower-stage electrode contacts with the first lower-stage gate wiring or the second lower-stage gate wiring and the finger wiring, and
the second upper-stage electrode contacts with the first main electrode or the second main electrode.

14. The semiconductor device according to claim 6, comprising:
a second lower-stage electrode that is provided in an internal portion of a second trench which is formed in the semiconductor substrate; and
a second upper-stage electrode that is provided on the second lower-stage electrode via an insulation film in the internal portion of the second trench, wherein
the second lower-stage electrode contacts with the first lower-stage gate wiring or the second lower-stage gate wiring and the finger wiring, and
the second upper-stage electrode contacts with the first lower-stage gate wiring or the second lower-stage gate wiring and the finger wiring.

15. The semiconductor device according to claim 1, wherein the semiconductor substrate is made with a wide band gap semiconductor.

16. The semiconductor device according to claim 15, wherein the wide band gap semiconductor is silicon carbide, gallium-nitride-based material or diamond.

17. The semiconductor device according to claim 6, wherein the semiconductor substrate is made with a wide band gap semiconductor.

18. The semiconductor device according to claim 17, wherein the wide band gap semiconductor is silicon carbide, gallium-nitride-based material or diamond.
